(19) United States
(12) Patent Application Publication
(10) Pub. No.: US 2012/0138130 A1
(43) Pub. Date: Jun. 7, 2012

(54) TUNNEL DIODES COMPRISING STRESS-COMPENSATED COMPOUND SEMICONDUCTOR LAYERS

(75) Inventors: Wolfgang Guter, Freiburg (GB); Frank Dimroth, Freiburg (DE); Jan Schöne, Reichenau (DE)

(73) Assignee: Fraunhofer-Gesellschaft zur Forderung der angewandten Forschung E.V., Muchen (DE)

(21) Appl. No.: 13/320,166

(22) PCT Filed: May 11, 2010
(86) PCT No.: PCT/EP2010/002907

§ 371 Date: Feb. 21, 2012

(30) Foreign Application Priority Data
May 11, 2009 (EP) 090063242.1

(51) Int. Cl. H01L 29/88; H01L 31/102

(52) U.S. Cl. 136/255; 257/104; 257/E29.339

(57) ABSTRACT

The invention relates to semiconductor components, in particular solar cells made of III-V compound semiconductors, as are used in terrestrial PV concentrator systems or for electrical energy supply in satellites. However it is also used in other optoelectronic components, such as lasers and light diodes, where either high tunnel current densities are necessary or special materials are used and where stress in the entire structure is not desired.

The invention relates to semiconductor components, in particular solar cells made of III-V compound semiconductors, as are used in terrestrial PV concentrator systems or for electrical energy supply in satellites. However it is also used in other optoelectronic components, such as lasers and light diodes, where either high tunnel current densities are necessary or special materials are used and where stress in the entire structure is not desired.

### STATE OF THE ART

Multiple solar cells consist of a plurality of p-n junctions comprising different semiconductor materials with a decreasing band gap. The semiconductor materials used are generally III-V compound semiconductors, such as e.g. gallium arsenide, and elementary semiconductors, such as silicon or germanium. However, also II-VI compound semiconductors, such as cadmium telluride, or mixed semiconductors, such as silicon germanium (SiGe) can be used. Multiple solar cells use the solar spectrum better than solar cells having only one p-n junction and therefore achieve the highest efficiencies [Dimroth, F., High-Efficiency Solar Cells from III-V Compound Semiconductors, Physica Status Solidi C, 2006, 3 (3): p. 373-9; Dimroth, F. and S. Kurtz, High-Efficiency Multifunction Solar Cells, MRS Bulletin, 2007, 32: p. 230-4]. Photoelectric conversion efficiencies of above 40% were achieved with triple cells.

The individual partial cells of multiple solar cells must be connected to each other electrically. This connection should be transparent and have a low electrical resistance. Therefore, interband tunnel diodes are used in current solar cell structures. Low electrical resistance is achieved due to the tunnel effect and, by suitable choice of semiconductor materials, a sufficiently high optical transparency is ensured [Bertness, K. A., D. J. Friedman and J. M. Olson, Tunnel junction interconnects in GaAs based multijunction solar cells, in Proceedings of the 24^{th} Photovoltaic Specialists Conference, 1994, Waikoloa, Hi., USA; Takamoto, T. et al., Two-terminal monolithic In_{0.5}Ga_{0.5}P/GaAs tandem solar cells with a high conversion efficiency of over 30%, Japanese Journal of Applied Physics, 1997, 36 (10): p. 6215-20].

For components made of a plurality of different semiconductor layers, generally a constant lattice constant matched to the substrate is required for all layers in order to minimise stresses and defects in the structure.

Nowadays, highly-efficient multiple solar cells made of III-V compound semiconductors are typically deposited on germanium (Ge) or gallium arsenide (GaAs) substrates by means of metallo-organic vapour-phase epitaxy (MOVPE). However also other methods, such as molecular beam epitaxy, are used. The most well known multiple solar cell comprises three p-n junctions, consisting of the compound semiconductors gallium indium phosphide (GaInP), gallium indium arsenide (GaInAs) and Ge [Stan, M. A. et al., The Development of >28% Efficient Triple-Junction Space Solar Cells at Emcore Photovoltaics, in Technical Digest of the 3^{rd} World Conference on Photovoltaic Energy Conversion, 2003, Osaka, Japan; Strobl, G. et al., Development and Qualification Status of European Triple Junction Solar Cells for Space Applications, in Proceedings of the 19^{th} European Photovoltaic Solar Energy Conference, 2004, Paris, France; Baur, C. et al., Triple Junction III-V based Concentrator Solar Cells: Perspectives and Challenges; Transactions of the ASME, Journal of Solar Energy Engineering, 2006, 129 (3): p. 258-65]. Such a structure can use the solar spectrum significantly more efficiently on the basis of the difference band gaps of the semiconductor materials which are used than for example solar cells made of silicon [Dimroth, F., High-Efficiency Solar Cells from III-V Compound Semiconductors, Physica Status Solidi C, 2006, 3 (3): p. 373-9]. What is crucial for the high efficiencies with which these solar cells convert sunlight into electrical energy is the high crystal quality of the semiconductor layers which are used. Crystal defects in the layers generally form recombination centres for the photoelectrically generated charge carriers and reduce the efficiency of the solar cell. Such defects can be avoided if all the semiconductor materials used have the same lattice constant. This is possible in the case of the triple solar cell having partial cells made of Ga0.5In_{0.5}P, Ga_{0.99}In_{0.01}As and Ge. All layers can be deposited on the Ge substrate for instance with the lattice constant of Ge.

The combination of partial solar cells made of Ga_{0.5}In_{0.5}P, Ga_{0.99}In_{0.01}As and Ge is however not yet adapted optimally to the solar spectrum. Materials having slightly lower band gap energies are desirable. This can be achieved for example by the GaInP and the GaInAs partial cells having more indium added (in a content between 5 and 17% [King, R. R. et al., 40% efficient metamorphic GaInP/GaInAs/Ge multijunction solar cells, Applied Physics Letters, 2007, 90: p. 183516-1-3; Fetzer, C. M. et al., High-Efficiency Metamorphic GaInP/GaInAs/Ge Solar Cells Grown by MOVPE, Journal of Crystal Growth, 2004, 261 (2-3): p. 341-8; Dimroth, F. et al., Metamorphic Ga_{y}In_{1-y}P/Ga₁₋ₓInₓAs Tandem Solar Cells for Space and for Terrestrial Concentrator Applications at C>1000 Suns, Progress in Photovoltaics: Research and Applications, 2001, 9 (3): p. 165-1 78]). Such changes in the composition of the semiconductor materials generally however influence not only the band gap thereof but also the lattice constant thereof [Levinshtein, M., S. Rumyantsev and M. Shur, Ternary and Quaternary III-V Compounds, Handbook Series on Semiconductor Parameters, Vol. 2. 1999, Singapore: World Scientific Publishing Co. Pte. Ltd.]. If therefore for example the combination of a Ga_{0.35}In_{0.65}P and Ga_{0.83}In_{0.17}As partial solar cell, adapted better to the solar spectrum, is deposited on the Ge substrate, then these layers have a lattice constant which is approx. 1% greater than germanium. This leads to the formation of crystal defects and to low efficiencies. In so-called buffer structures between substrates and the lattice-mismatched partial solar cells, the lattice constant is therefore continuously or gradually changed. It is thereby possible to locate the crystal defects very readily in these buffer structures [Schöne, J. et al., Misfit Dislocation Blocking by Dilute Nitride Intermediate Layers, Applied Physics Letters, 2008, 92 (8): p. 081905; Geisz, J. F. et al., 40.8% efficient inverted triple-junction solar cell with two independently metamorphic junctions, Applied Physics Letters, 2008, 93 (12): p. 123505/1-3]. If it is achieved that only very few defects extend into the photoactive layers of the partial cells (<10⁶ cm⁻³), very high efficiencies can likewise be achieved [King, R. R. et al., 40% efficient metamorphic GaInP/GaInAs/Ge multijunction solar cells, Applied Physics Letters, 2007, 90: p. 183516-1-3 8].

The use of highly-efficient III-V multiple solar cells resides nowadays, on the one hand, in the energy supply of satellites and probes in space [King, R. R. et al., Advanced III-V Multijunction Cell for Space, in Proceedings of the 4^{th} World Conference on Photovoltaic Energy Conversion, 2006, Waikoloa, Hi., USA; Meusel, M. et al., Development and Production of European III-V Multijunction Solar Cells, in Proceedings of the 22^{nd} European Photovoltaic Solar Energy Conference and Exhibition, 2007, Milan, Italy], and, on the other hand, in terrestrial PV concentrator systems [Bett, A. W. and H. Lerchenmueller, the FLATCON® System from Concentrix Solar, in Concentrator Photovoltaics, 2007, Springer-Press GmbH, p. 301-1 9; Lerchenmueller, H. et al., from FLATCON® Pilot Systems to the first Power Plant, in Proceedings of the International Conference on Solar Concentrators for the Generation of Electricity or Hydrogen, 2007, EI Escorial, Spain].

The partial solar cells of multiple solar cells are connected to each other electrically typically by tunnel diodes. These diodes consist predominantly of semiconductor layers doped until degeneration [Esaki, L., Discovery of the tunnel diode, IEEE Transactions on Electron Devices, 1976, ED-23 (7): p. 644-7] and are used, in addition to photovoltaics, above all also in high-frequency technology and optoelectronics. In light diodes (LEDs) and laser diodes (e.g. VCSELs), tunnel diodes are used for example in order to change the polarity of the material. By changing the polarity from p to n, resistance losses and non-homogeneous distribution of the current flow can be reduced on the basis of the higher charge carrier mobility [Manish Mehta et al., Electrical Design Optimization of Single-Mode Tunnel-Junction-Based Long Wavelength VCSELs, IEEE JOURNAL OF QUANTUM ELECTRONICS, 2006, 42 (7): p. 675; Seong-Ran Jeon et al., GaN-Based Light-Emitting Diodes Using Tunnel Junctions, IEEE JOURNAL OF SELECTED TOPICS IN QUANTUM ELECTRONICS, 2002, 8 (4): p. 739]. In addition, the free charge carrier absorption of n-material is generally less than in p-material. Hence also optical losses are reduced (Manish Mehta et al., Electrical Design Optimization of Single-Mode Tunnel-Junction-based Long Wavelength VCSELs, IEEE JOURNAL OF QUANTUM ELECTRONICS, 2006, 42 (7): p. 675; Edmond, J. A. et al., Blue Light-Emitting Diode with Degenerate Junction Structure, 1994, Cree Research, Inc., Durham, N.C., U.S. Pat. No. 1,252,84]. Analogously to multiple solar cells, the individual cavities in cascade lasers are likewise connected to tunnel diodes [W. J. Siskaninetz et al., Reduced power consumption in GaAs-based bipolar cascade lasers, IEEE Electronic Letters, 2002, 38 (21): p. 1259]. In the case of VCSELs, an optical and electrical aperture for higher power densities is produced either by oxides or by means of tunnel diodes [A. Bachmann et al., Continuous-wave Operation of electrically pumped GaSb-based vertical cavity surface emitting laser at 2.3 mm, IEEE Electronic Letters, 2008, 44 (3): p. 202].

The use of tunnel diodes as connection element is so attractive because they can satisfy the high requirements with respect to electrical and optical properties. In order to transport the high photocurrents in the concentrator system even under highly-concentrated light, the electrical resistance of the tunnel diode must be very low. A high electrical resistance, as for example a normal p-n diode has, leads to high losses. For the tunnel diode, high tunnel current densities must therefore be achieved, which is produced above all by very highly-doped semiconductors with a small band gap. In addition, the tunnel diode should absorb no light which is used in partial cells situated thereunder also for photoelectrical energy conversion. This is achieved by thin layers made of indirect or high-band gap semiconductor materials [Takamoto, T. et al., Mechanism of Zn and Si diffusion from a highly doped tunnel junction for InGaP/GaAs tandem solar cells, Journal of Applied Physics, 1999, 85 (3): p. 1481-6]. The epitaxy of highly-doped III-V compound semiconductors has been examined worldwide by numerous research groups [Scheffer, F. et al., High doping performance of lattice matched GaInP on GaAs, Journal of Crystal Growth, 1992, 124 (1-4): p. 475-82; Keiper, D., R. Westphalen and G. Landgren, Comparison of carbon doping of InGaAs and GaAs by CBr₄ using hydrogen or nitrogen as carrier gas in LP-MOVPE, Journal of Crystal Growth, 1999, 197 (1-2): p. 25-30; Bettini, J. et al., Analysis of Be doping of InGaP lattice matched to GaAs, Journal of Crystal Growth, 2000, 208 (1-4): p. 65-72; Dimroth, F. et al., High C-doping of MOVPE Grown Thin AlₓGa₁₋ₓAs Layers for AlGaAs/GaAs Interband Tunneling Devices, Journal of Electronic Materials, 2000, 29 (1): p. 47-52; Mimila Arroyo, J. et al., Carbon acceptor doping efficiency in GaAs grown by metalorganic chemical vapor deposition, Applied Physics Letters, 2001, 79 (19): p. 3095-7]. The tunnel diodes are generally embedded directly in the semiconductor layer stack and often consist of more than the two absolutely necessary n- or p-doped layers. Thus for example barrier layers are fitted around the p-n junction of the tunnel diode in order to suppress the diffusion of the dopants from the highly-doped layers [Kojima, N. et al., Analysis of impurity diffusion from tunnel diodes and optimisation for operation in tandem cells, Solar Energy Materials and Solar Cells, 1998, 50 (1-4): p. 237-42]. In addition, also potential holes can be generated next to the tunnel junction by means of barrier layers with a higher band gap or lower doping, as a result of which a resonant interband-tunnel diode is produced [Niu Jin et al., 151 kA/cm² peak current densities in Si/SiGe resonant interband tunnelling diodes for high-power mixed-signal applications, Applied Physics Letters, 2003, 83 (16): p. 3308].

All semiconductor layers of the tunnel diodes should generally be deposited lattice-matched to the surrounding semiconductor materials. Although the layers are normally thinner than the critical layer thickness, these can generate thread dislocations by crystal stress which extend into the partial cells and greatly reduce the efficiency of the solar cell structure [Guter, W. et al., Investigation and Development of III-V Triple-Junction Concentrator Solar Cells, in Proceedings of the 22^{nd} European Photovoltaic Solar Energy Conference and Exhibition, 2007, Milan, Italy]. In current III-V multiple solar cells or other optoelectronic components, tunnel diodes are therefore deposited, as well as possible, lattice-matched to the surrounding semiconductor layers.

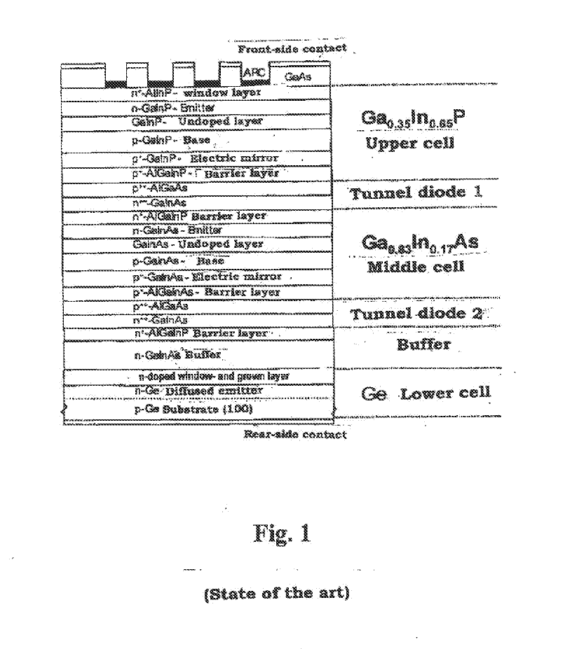

In the last few years, metamorphic deposition of semiconductor layers has been established increasingly in addition to the lattice-matched growth of different semiconductor layers one upon the other [Dimroth, F. et al., Metamorphic Ga_{y}In_{1-y}P/Ga₁₋ₓInₓAs Tandem Solar Cells for Space and for Terrestrial Concentrator Applications at C>1000 Suns, Progress in Photovoltaics: Research and Applications, 2001, 9 (3): p. 165-1 78]. In order to achieve better matching of the individual partial solar cells of a triple cell to the solar spectrum, for example a buffer is produced between the lowermost cell made of germanium, which buffer increases the lattice constant. In this buffer layer, a dense dislocation network is produced by the mismatching. An important object of such a buffer is however also that these dislocations do not penetrate into the photoactive parts of the cell stack but remain localised in the buffer. FIG. 1 illustrates the layer structure of a metamorphic triple solar cell. After a lattice-matched window layer has been applied on the Ge substrate, the lattice constant is increased in a GaInAs buffer by an increasing In content. Thereafter, tunnel diodes are deposited lattice-matched to the layers of the GaInAs central cell and to the uppermost layer of the buffer. All layers after the buffer are extensively lattice-matched to each other.

An extension of the concept is the inverted metamorphic triple solar cell. The individual semiconductor layers are thereby deposited for example on a GaAs substrate, on the one hand, in reverse sequence, which is thereafter removed [Geisz, I. F. et al., Inverted GaInP/(In)GaAs/InGaAs Triple-Junction Solar Cells with Low-Stress Metamorphic Bottom Junctions, in Proceedings of the 33^{rd} IEEE PVSC, 2008, San Diego]. In order to be even freer in the choice of individual partial solar cells, buffer structures described above can also be inserted between all partial cells. As a result, each partial cell can have a different lattice constant. All layers between the buffer structures are however lattice-matched to each other. This applies also for the tunnel diodes which are situated above or below the partial cell [Geisz, I. F. et al., Inverted GaInP/(In)GaAs/InGaAs Triple-Junction Solar Cells with Low-Stress Metamorphic Bottom Junctions, in Proceedings of the 33^{rd} IEEE PVSC, 2008, San Diego].

### Disadvantages of the State of the Art

The boundary condition of the lattice matching is a great restriction on usable material combinations. In order to produce highly-transparent tunnel diodes, it would be desirable to use high-band gap, indirect and very thin semiconductor layers for this purpose. In order to produce a high tunnel current density, it would be desirable to use highly-doped, low-band gap semiconductor layers which form an optimum semiconductor heterojunction (Type III). It is immediately clear that a compromise of transparency and tunnel current density must be adopted for the band gap. It is all the more important to produce the other semiconductor properties, such as indirect band gap of the p-doped layer and high doping. It is thereby difficult to maintain the lattice matching. If the lattice constant of the semiconductor layers in the tunnel diode is chosen to be too small or too large, sufficient stress is built up to generate crystal defects, even with thin, only slightly stressed layers which extend also into surrounding semiconductor layers. The thickness of the tunnel diode layers must thereby in no way exceed the critical layer thickness.

In lattice-matched triple solar cells on Ge, there is therefore essentially a restriction to (AlₓGa₁₋ₓ)_{0.99}In_{0.01}As and (AlₓGa₁₋ₓ)_{0.5}In_{0.5}P. Since in metamorphic triple cells the partial cells consist of GaInAs with up to 40% In and of GaInP with up to 65% In, there is a restriction in the latter, according to the material, also to AlGaInAs with indium contents up to 40% and AlGaInP with indium contents up to 65%. In particular the use of indirect semiconductor materials with a low band gap and of semiconductor interfaces with a type III heterojunction is thus only possible in a restricted manner. A higher carbon content in AlGaInAs reduces in addition the lattice constant thereof, which can be compensated for example by a higher indium content.

As a result of the high indium content in AlGaInAs in the case of metamorphic structures, these layers are more difficult to p-dope. Carbon halogens, such as carbon tetrabromide (CBr₄), reduce the indium incorporation so that no lattice matching of the layer is possible [Guter, W. et al., Investigation and Development of III-V Triple-Junction Concentrator Solar Cells, in Proceedings of the 22^{nd} European Photovoltaic Solar Energy Conference and Exhibition, 2007, Milan, Italy]. In the case of intrinsic doping with carbon from the organic groups of metallo-organics, a large part of the incorporated carbon is not electrically active because it is passivated with hydrogen [Oda Y. et al., Suppression of hydrogen passivation in carbon-doped GaAsSb grown by MOCVD, Journal of Crystal Growth, 2004, 261 (2-3): p. 393-397]. In this case, a compromise between lattice matching and doping must therefore be adopted. Either a lattice-mismatched tunnel diode layer is accepted, which greatly reduces the efficiency of the solar cell or a low p-doping is accepted. Then the cell structure is however not suitable for highly-concentrating photovoltaic systems because of the tunnel diode.

According to the current state of the art, it is not possible to produce tunnel diodes with very high tunnel currents in metamorphic structures. In the past, often mismatched layers were accepted. These generate crystal defects which reduce the efficiency of the solar cell structure.

### Presentation of the Problem to be Resolved

Since the semiconductor layers of the tunnel diodes must be grown to be lattice-matched to the surrounding semiconductor layers, the lattice matching represents a strict boundary condition in the construction thereof. Although the layers of the tunnel diode are generally very thin, these can lead to crystal defects if they are produced with stress, which crystal defects extend into the photoactive layers of the solar cell and reduce the efficiency thereof. The requirement for lattice matching however greatly restricts the choice of possible compound semiconductor materials. For the tunnel diode, important properties, such as high doping and matching band structure, cannot be set optimally.

It is therefore the object of the present invention to relax the boundary condition that all layers should be produced lattice-matched to each other and hence to enable a greater choice of material for semiconductor layers which are deposited in particular one upon the other.

This object is achieved, with respect to the semiconductor component, by the features of patent claim 1, with respect to a specially configured solar cell, by the features of patent claim 14 and also purposes of use of the component by the features of patent claim 15. The dependent patent claims thereby represent advantageous developments.

According to the invention, a semiconductor component is hence provided, comprising at least one layer sequence of a tunnel diode which is disposed between two semiconductor layers in the manner of a sandwich, the tunnel diode comprising at least one degenerate n-conducting layer and also one degenerate p-conducting layer, with the proviso that the layers have respectively a thickness between 10 nm and 100 nm and the lattice constants of the materials of the degenerate layers have a difference of at least 0.5%.

The present invention describes hence semiconductor components having tunnel diodes made from stress-compensated semiconductor layers. There is understood by stress compensation, the method of depositing a thin semiconductor layer pseudomorphically, i.e. elastically stressed, and of compensating for the resulting stress by compensation with a layer stressed in the other direction. According to the invention, stress due to a stressed layer with too large a lattice constant is described as a “layer stressed in compression” and a layer stressed with too small a lattice constant as a “layer stressed in tension” so that a layer stressed in tension is compensated for by a layer stressed in compression. For this purpose, the critical layer thickness, set after this dislocation formation, must not be exceeded in the respective layer. Such methods are used nowadays for instance in the production of quantum holes. Since tunnel diodes generally consist of thin layers, the method of stress compensation can also be applied in this component. This relaxes the requirement for lattice matching as long as simply the combination of a plurality of layers is not intended to trigger stress. The individual layers may however be stressed. The requirement for a constant lattice constant can be relaxed with these stress-compensated tunnel diodes. Therefore materials with a different lattice constant may therefore be used as long as the stress is minimised by the layers. As a result, the selection of possible semiconductor materials for the production of tunnel diodes is significantly increased. In addition, the properties of the tunnel diodes can be improved by stressed layers. Interface states which are induced by local stress can increase for example the maximum tunnel current density by a multiple. As a result of stress compensation, crystal defects outside the tunnel diodes are avoided.

According to the invention, it is hence provided in a first embodiment that the materials of the degenerate layers have different lattice constants relative to each other. The difference in lattice constants must thereby be at least 0.5% to at most 5%, preferably at least 1% to at most 2%. If these layers are deposited one upon the other by methods known from the state of the art, stress to the layers relative to each other is effected. If hence a layer with a greater lattice constant is grown on a layer with a smaller lattice constant, then the crystal lattice of the layer with the smaller lattice constant is stretched in the growth plane. Correspondingly, the crystal lattice of the layer with the greater lattice constant is compressed. If for example a degenerate p-conducting layer made of a material with a greater lattice constant than the material of the degenerate n-conducting layer is deposited on this layer, then stress as described above is effected. For the first example in which the material of the p-conducting layer has an actually greater lattice constant than the material of the n-conducting layer, this is then termed, as explained above, a deposited layer which is stressed in compression. In the reverse case, for example in the case where the lattice constant of the material of one of the degenerate p-conducting layers which is intended to be deposited on an n-conducting layer, has a smaller lattice constant than the material of the n-conducting layer, the thus deposited degenerate p-conducting layer is described as layer stressed in tension.

According to the invention, it is preferred in the case of the semiconductor component, in a first embodiment, if the averaged lattice constants of the degenerate layers essentially correspond to the lattice constant of the materials of the surrounding semiconductor layers. There is essentially jointly included, according to the invention, a deviation of the averaged lattice constants of the degenerate layers to the surrounding semiconductor layers of up to 0.5%.

Of course, the invention also comprises an embodiment in which stress between a degenerate layer and a surrounding semiconductor layer is produced.

The materials which are possible for the degenerate layers and surrounding semiconducting layers can be selected, independently of each other, from the group consisting of Ge, Si, SiGe, GaAs, GaSb, GaInP, AlGaAs, GaInAs, GaPN, GaInAsSb, GaInNAs, GaInAsPN, AlGaInP, AlGaInAs, AlGaAsSb, AlGaInP, GaAsSb, AlGaSb, InN, GaAsP and/or AlGaInNAs. The materials are thereby chosen such that they fulfil the requirements of claim 1, i.e. materials which have a different lattice constant at least by 0.5% are chosen. The lattice constants are known to the person skilled in the art with reference to known diagrams which describe the correlation between the compositions of the semiconductor compounds and the lattice constants. In this respect, a wide a variation of materials is possible. This enables completely novel solar cells or an improved current conduction between the partial solar cells which are connected via a tunnel diode according to the invention.

Preferably, the degenerate p-conducting layer is doped with carbon, likewise the n-conducting degenerate layer can be doped with tellurium, silicon and/or germanium.

Substantial advantages accompany the semiconductor components according to the invention which contain tunnel diodes defined according to the invention.

Such tunnel diodes have a higher tunnel current density and allow the use of the solar cell even in highly-concentrating photovoltaic systems. Due to stress-compensated layers in the tunnel diode, also semiconductor junctions made of further materials, which have a better band arrangement, such as for example InN/AlGaSb, or GaSb/InAs, or GaAs/GaSb, can be produced. This also increases the maximum achievable tunnel current of the tunnel diode.

In concrete terms, the tensile stress of a highly carbon-doped AlGaAs layer in the tunnel diode of a metamorphic triple solar cell can be compensated for by a layer stressed in compression, such as GaInAs or GaInP, with a very high indium content. A tunnel diode with highly-doped layers can therefore be produced, which tunnel diode does not generate any defects which extend into the partial solar cells.

With stress-compensated tunnel diodes, an extensively transparent partial cell connection with low electrical resistance and low generation of crystal defects outside the tunnel diode is possible. In addition, more optimal material combinations for the tunnel diodes can be used also in other solar cell structures if the lattice matching is replaced by the stress compensation as boundary condition for production.

The invention comprises furthermore also semiconductor components which are constructed as described above, however the at least one layer sequence comprising in addition at least one barrier layer with a layer thickness of 10 nm to 100 nm, the barrier layer(s) respectively being disposed between the degenerate layers and the surrounding semiconductor layers.

It is thereby advantageous if the surrounding semiconductor layers have a higher band gap energy than the degenerate layers.

Further preferred constructions of the semiconductor components are possible due to this embodiment.

The advantage of this embodiment now resides in the fact that a stress compensation can be achieved not only between the degenerate layers of the tunnel diode but also in addition between the barrier layers, which are likewise configured as thin layers, and the respectively abutting degenerate layers.

Preferably, the above-described semiconductor component is thereby constructed in a first variant, such that the lattice constants of the materials of the degenerate layers are stress-compensated and essentially equal to the lattice constants of the semiconductor layers and of the barrier layers.

A further embodiment then provides that the lattice constants of the materials of a degenerate layer of the tunnel diode are greater or smaller than the lattice constant of the abutting barrier layer. As a result, constructions are now possible in which the averaged lattice constants of the materials of the degenerate layer and of the barrier layer are essentially equal to the surrounding semiconductor layers. For the previously described embodiment with a layer sequence in which additional barrier layers are provided, the difference between the lattice constants of the degenerate layers and the barrier layers can be preferably again at least 0.5%. Preferably, the difference of the lattice constants is at least 0.5% to at most 5%, particularly preferred 0.1% to at most 2%.

According to the invention, a solar cell which comprises at least one previously described semiconductor component is likewise provided.

Possibilities of use of the semiconductor component according to the invention are found in solar technology, as multiple solar cell, as laser diode or as light diode.

The concept according to the invention is explained in more detail with reference to the subsequent embodiments, given by way of example, and the Figures without wishing to restrict the invention to the represented embodiments.

There are thereby shown

FIG. 1 the schematic construction of a metamorphic triple solar cell according to the state of the art.

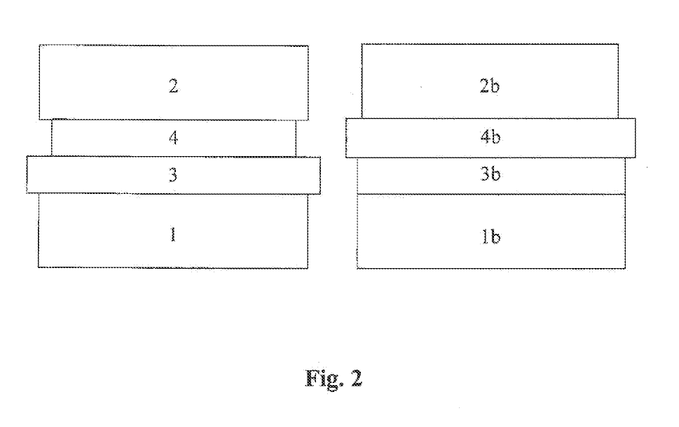

FIG. 2 two embodiments according to the invention of a semiconductor component.

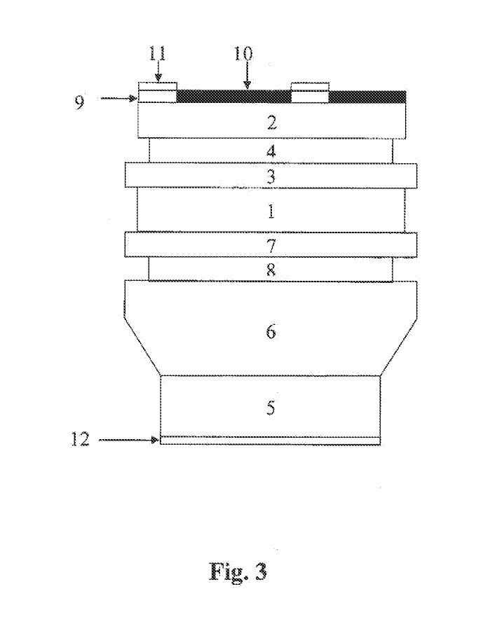

FIG. 3 a metamorphic triple solar cell which comprises a semiconductor component with two tunnel diodes according to the invention.

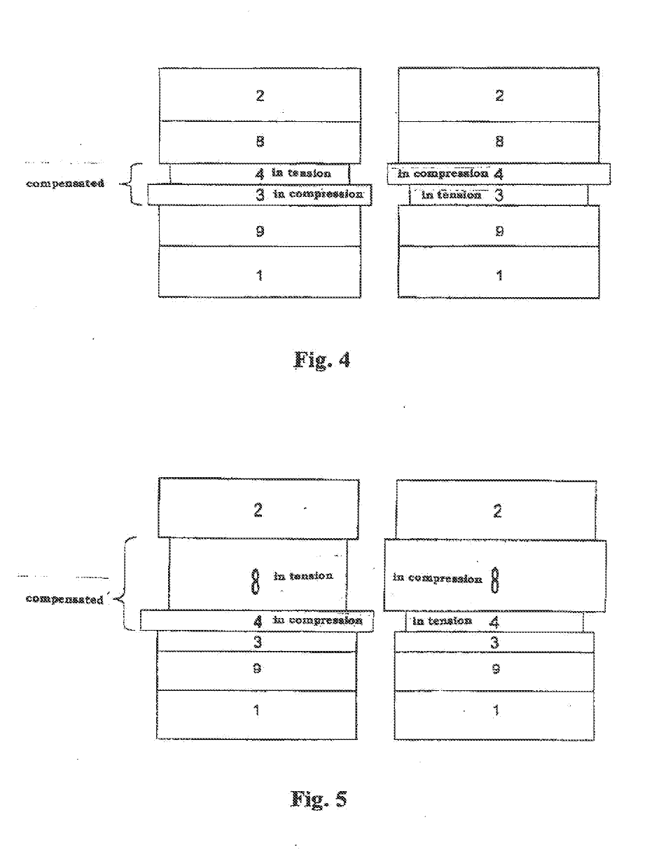

FIG. 4 a further embodiment of a semiconductor component with barrier layers.

FIG. 5 an embodiment of the invention with barrier layers and stress compensator with the barrier layer.

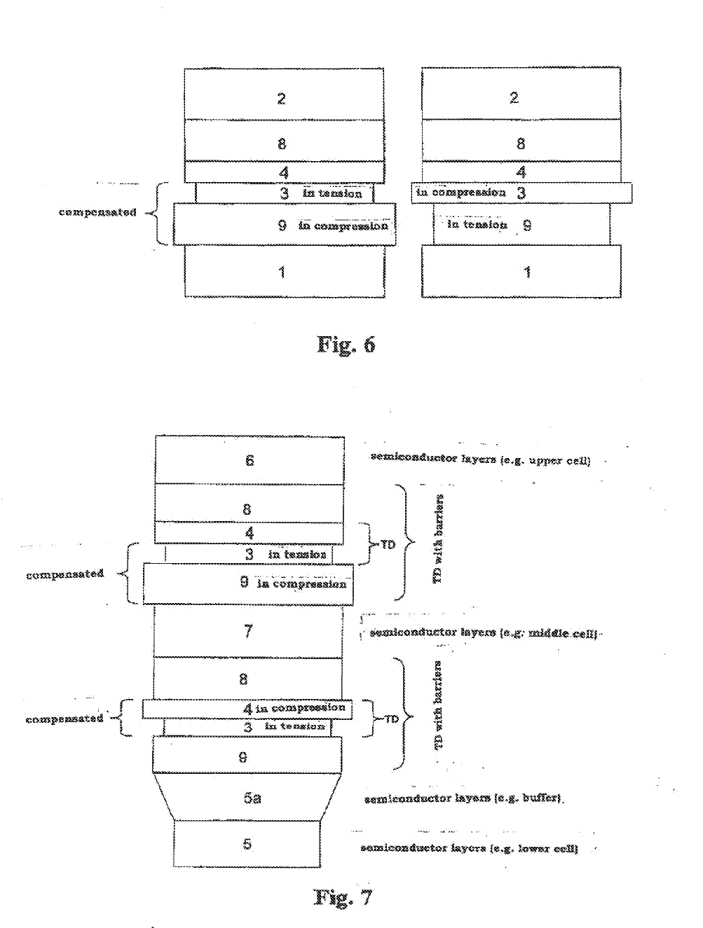

FIG. 6 a modification of the embodiment according to FIG. 5.

FIG. 7 the construction of a metamorphic triple solar cell.

FIG. 2 shows two layer sequences according to the invention comprising two semiconductor layers 1 and 2, between which the two layers 3 and 4 of the tunnel diode are included in the manner of a sandwich. The different width of the respective layers indicated in the Figures thereby represents the original lattice constant of the materials used respectively for the layers. In the left-hand embodiment of the semiconductor component according to the invention of FIG. 2, the material of layer 3 hence has a greater lattice constant relative to layer 1 (stressed in compression), whilst the lattice constant of the material of layer 4 is less than the lattice constant of the material 3 (stressed in tension). The material of layer 2 has a lattice constant which is approximately of equal size to the material which is used for layer 1. In the case of the semiconductor component of the left-hand embodiment of FIG. 2, hence both layer 3 is stressed on layer 1 and layer 4 stressed on layer 3. As a result, a stress compensation with the layer 3, 4 is achieved, the averaged lattice constant of which corresponds approximately to the semiconductor layer.

In the right-hand embodiment of FIG. 2, the material used for the layer 3 of the tunnel diode has a lattice constant which is approximately of equal size to the material used for the layer 1 of the semiconductor composite. Stresses hereby occur hence in the junction of layer 3 to layer 4 and also from layer 4 to layer 2. The material for layer 4 thereby has a greater lattice constant than the materials used for the layers 3 or 2.

FIG. 3 shows a possible embodiment of a stress-compensated semiconductor component in a metamorphic triple solar cell structure having GaInP upper cell 2, GaInAs central cell 1, GaInAs buffer structure 6 and Ge substrate 5. For the stress-compensated tunnel diode layers, for example GaInAs 3 and AlGaAs 4 or AlGaAsSb 7 and GaAs 8 can be used. There are in addition a highly doped cap layer 9, an antireflection layer 10, a front-side contact 11 and a rear-side contact 12. The lattice constant here is also illustrated by a different width of the boxes.

As an alternative, the solar cell structure need not be metamorphic. Then a buffer layer 6 is not absolutely required and the respective indium contents of the partial cells are different according to the substrate. Correspondingly, the layer thickness of the stress-compensated tunnel diodes requires to be matched also.

Furthermore, also other materials could be used for the partial cells of the multiple solar cell, the buffer layer or the tunnel diode layers. For example AlGaInP 2, AlGaInAs 1 and GaInNAs 5 or the tunnel diodes are used in double, quadruple or quintuple cells. In the case of the quintuple cell, the partial cells can consist for example of AlGaInP, GaInP, AlGaInAs, GaInAs and Ge.

In addition, the stress-compensated tunnel diode can also be used in other optoelectronic components, such as lasers (VCSEL with tunnel contact), light diodes or insulated tunnel diodes.

The individual layers of the tunnel diode preferably consist of AlGaInAs which is stressed in compression and AlGaInAs which is stressed in tension, of AlGaInP which is stressed in compression and AlGaInP which is stressed in tension, of AlGaInAs which is stressed in compression and AlGaInP which is stressed in tension or of AlGaInP which is stressed in compression and AlGaInAs which is stressed in tension.

The stress-compensated tunnel diode can be used in tandem solar cells having two p-n junctions made of GaInP and Ga(In)As, of Ga(In)As and Ge or of AlGa(In)As and Ga(In)As. The stress-compensated tunnel diode can likewise be used in triple solar cells having three p-n junctions made of GaInP, GaInAs and Ge, of AlGaInAs, GaInAs and Ge, of AlGaInP and GaInAs and Ge. A triple solar cell with the stress-compensated tunnel diode having three p-n junctions made of GaInP, GaAs and GaInAs or of AlGaInP, GaAs and GaInAs is likewise possible. The stress-compensated tunnel diode can also be used in quadruple solar cells having four p-n junctions made of (Al)GaInP, (Al)GaInAs, (Al)GaInNAs and Ge. Furthermore, the stress-compensated tunnel diode can be used in quintuple or sextuple solar cells having five of six p-n junctions made of AlGaInP, GaInP, AlGaInAs, GaInAs, and GaInNAs and/or Ge.

Analogously in construction to FIG. 2, FIG. 4 now shows schematically the construction according to the invention of a semiconductor component.

The embodiment shown in FIG. 4, left part, now shows an example in which in addition barrier layers 8, 9 are disposed between the degenerate layers 3, 4 and the semiconductor layers 1, 2.

In the embodiment according to FIG. 4, left part, the construction of the degenerate layers 3, 4 is now chosen such that one layer, layer 3 in the example case here, has a greater lattice constant than layer 4, which is illustrated symbolically by the greater width so that layer 3 is stressed in compression. Layer 4 is grown stressed in tension in order to produce the stress compensation. The averaged lattice constants of these layers now correspond essentially to the lattice constants of the materials of the semiconducting layers 1, 2.

Of course, an embodiment is likewise possible in which the p-conducting layer 4 is stressed in compression, i.e. has a greater lattice constant, and the n-conducting degenerate layer 3 has a smaller lattice constant and hence is stressed in tension so that again as a result the averaged lattice constants of the materials of layers 3 and 4 correspond however essentially to the lattice constants of the semiconducting layers 1, 2.

In FIG. 5, a further embodiment is now represented, in which stress compensation between the tunnel diode layers and the barrier layers is produced. In the example case according to FIG. 5, left part, the degenerate p-conducting layer 4 is thereby stressed in compression, i.e. it has a greater lattice constant than the abutting layer 3. It is now crucial that the averaged lattice constants of the layers 4 and 8 now again correspond to the lattice constants of the materials of the surrounding semiconducting layers 1, 2. As a result, the layer 8 is hence stressed in tension and the other layer 4 in compression.

In the right part, a reverse construction is now chosen, i.e. the barrier layer 8 is stressed here in compression and the p-conducting degenerate layer 4 is stressed in tension. As a result, in comparison to the surrounding semiconductor layers 1, 2, again here also matching of the lattice constants is however effected.

Finally, FIG. 6 also shows a further possibility as to how a semiconductor component according to the invention can be constructed. Again a stress compensation is also now achieved here between the tunnel diode layers 3 and the barrier layers 9. In the left part of FIG. 6, layer 3 is stressed now in tension and layer 9 in compression, whereas, in the right part, layer 9 is stressed in tension and layer 3 in compression, here again, in comparison to the surrounding semiconductor layers 1, 2 when the averaged material constants are determined, an adaptation being produced.

FIG. 7 now shows an application example in a metamorphic triple solar cell. Layers 5 and/or 6 can thereby also consist of a plurality of semiconductor layers and possibly form a solar cell. The barrier layers 8, 9 of the lower tunnel diode and also the barrier layer 8 of the upper tunnel diode are optional. Barrier layer 9 of the upper tunnel diode is used, in this case, for stress compensation. Compensation means that the average lattice constant of the stressed layers corresponds to the surrounding semiconductor layers. This applies also in the case of metamorphic structures where the surrounding semiconductor layers 1, 2 and 7 are meant and not layers 5 and/or 5a which have a different or an undefined lattice constant.

What is claimed is:

1. A semiconductor component, comprising at least one layer sequence of a tunnel diode which is disposed between two semiconductor layers in the manner of a sandwich, the tunnel diode comprising at least one degenerate n-conducting layer and also one degenerate p-conducting layer, wherein the degenerate layers have respectively a thickness between 10 nm and 100 nm and the lattice constants of the materials of the degenerate layers have a difference of at least 0.5%.

2. The semiconductor component according to claim 1, wherein the difference between the lattice constants is at least 0.5% to at most 5%.

3. The semiconductor component according to claim 1, wherein the averaged lattice constant of the degenerate layers corresponds essentially to the lattice constant of the materials of the two semiconductor layers.

4. The semiconductor component according to claim 1, wherein the dislocation relaxation of the degenerate layers is at most 50%.

5. The semiconductor component according to claim 1, wherein the layer materials of the semiconductor layers and degenerate layers are selected, independently of each other, from the group consisting of Ge, Si, SiGe, GaAs, GaSb, GaInP, AlGaAs, GaInAs, GaPN, GaInAsSb, GaInNAs, GaInAsPN, AlGaInP, AlGaInAs, AlGaAsSb, AlGaInP, GaAsSb, AlGaSb, InN, GaAsP and/or AlGaInNAs.

6. The semiconductor component according to claim 1, wherein the p-conducting layer is doped with carbon and/or the n-conducting layer with tellurium, silicon and/or germanium.

7. The semiconductor component according to claim 1, wherein the tunnel diode comprises at least one layer sequence of first and second barrier layers with a layer thickness of 10 nm to 100 nm, the barrier layers being disposed between the degenerate layers and the semiconductor layers.

8. The semiconductor component according to claim 1, wherein the second barrier layer has a higher band gap energy than the degenerate n-conducting layer and/or the first barrier layer has a higher band gap energy than the degenerate p-conducting layer.

9. The semiconductor component according to claim 8, wherein the averaged lattice constants of the materials of the degenerate layers are essentially equal to the lattice constants of the materials of the semiconductor layers.

10. The semiconductor component according to claim 8, wherein the lattice constants of the materials of the degenerate layers are greater or smaller than the lattice constants of the materials of the first and second barrier layers.

11. The semiconductor component according to claim 10 wherein the averaged lattice constants of the materials of the degenerate layers and of the first and second barrier layers are essentially equal to the lattice constants of the materials of the semiconducting layers.

12. The semiconductor component according to claim 1, wherein at least one of the semiconductor layers comprise
semiconductor materials with a p-n junction, or
semiconductor materials without a p-n junction against which respectively at least one further semiconductor layer, which has preferably a p-n junction, abuts.

13. The semiconductor component according to claim 1, wherein a further tunnel diode abuts against at least one of the semiconductor layers iteratively and also at least one further layer sequence abuts against the further tunnel diode.

14. A solar cell, comprising at least one semiconductor component including at least one layer sequence of a tunnel diode which is disposed between two semiconductor layers in the manner of a sandwich, the tunnel diode comprising at least one degenerate n-conducting layer and also one degenerate p-conducting layer, wherein the degenerate layers have respectively a thickness between 10 nm and 100 nm and the lattice constants of the materials of the degenerate layers have a difference of at least 0.5%.

15. A method comprising:
using of a semiconductor component including at least one layer sequence of a tunnel diode which is disposed between two semiconductor layers in the manner of a sandwich, the tunnel diode comprising at least one degenerate n-conducting layer and also one degenerate p-conducting layer, wherein the degenerate layers have respectively a thickness between 10 nm and 100 nm and the lattice constants of the materials of the degenerate layers have a difference of at least 0.5% as solar cell, multiple solar cell, laser diode or light diode.
